(19) United States
(12) Patent Application Publication
(10) Pub. No.: US 2026/0136918 A1
(43) Pub. Date: May 14, 2026

(54) INTEGRATED CIRCUIT DEVICES INCLUDING STACKED TRANSISTORS WITH OFFSET POWER DELIVERY NETWORK SCHEME ON OPPOSITE SIDES OF CELL STRUCTURE

(71) Applicant: Samsung Electronics Co., Ltd., Suwon-si (KR)

(72) Inventors: JINYOUNG LIM, Schenectady, NY (US); YOUNG GOOK PARK, Resselaer, NY (US); HYOJONG SHIN, Mechanicville, NY (US); KANG-ILL SEO, Springfield, VA (US)

(21) Appl. No.: 19/197,327

(22) Filed: May 2, 2025

Related U.S. Application Data
(60) Provisional application No. 63/719,715, filed on Nov. 13, 2024.

(51) Int. Cl. H01L 23/528; H01L 23/522; H10D 84/83

(52) U.S. Cl. CPC H10W 20/435; H10D 84/83125; H10W 20/42; H10W 20/43

(57) ABSTRACT

An integrated circuit devices may include a cell structure that comprises: a substrate; a first cell boundary; and a second cell boundary that is opposite to the first cell boundary with respect to the cell structure in a horizontal direction; an upper transistor on an upper surface of the substrate; a lower transistor between the upper surface of the substrate and the upper transistor in a vertical direction; front-side routing tracks on the upper transistor; back-side routing tracks on a lower surface of the substrate; a front-side power delivery network that is adjacent one of the front-side routing tracks; and a back-side power delivery network that is adjacent one of the back-side routing tracks, wherein the front-side power delivery network overlaps the first cell boundary in the vertical direction, and wherein the back-side power delivery network overlaps the second cell boundary in the vertical direction.

### CROSS-REFERENCE TO RELATED APPLICATIONS

The present application claims the benefit of U.S. Provisional Patent Application Ser. No. 63/719,715, filed on Nov. 13, 2024, entitled STACKED TRANSISTORS WITH SHARED POWER DELIVERY NETWORK SCHEME AND METHODS OF MANUFACTURING THE SAME, the disclosure of which is hereby incorporated herein in its entirety by reference.

### BACKGROUND

The present disclosure generally relates to the field of integrated circuit devices and, more particularly, to integrated circuit devices including stacked transistors.

Various structures of an integrated circuit device and methods of forming the same have been proposed to increase the integration density. For example, a stacked transistor structure including multiple transistors vertically stacked has been proposed.

### SUMMARY

An aspect of the present disclosure is to provide integrated circuit devices with improved electrical characteristics and reliability characteristics, and methods for manufacturing the same. More specifically, an aspect of the present disclosure is to provide integrated circuit devices, including a stacked transistor structure comprising a front-side power delivery network and a back-side power delivery network at different locations (e.g., different cell boundaries) to scale down the integrated circuit devices, reduce the source resistance, and increase process margin. However, it will be understood that the embodiments, goals, and benefits of the present disclosure are not limited to the descriptions above.

An integrated circuit device, according to some embodiments, may include a cell structure that comprises: a substrate; a first cell boundary; and a second cell boundary that is opposite to the first cell boundary with respect to the cell structure in a horizontal direction that is parallel with an upper surface of the substrate; an upper transistor on the upper surface of the substrate, wherein the upper transistor is between the first cell boundary and the second cell boundary in the horizontal direction; a lower transistor between the upper surface of the substrate and the upper transistor in a vertical direction that is perpendicular to the upper surface of the substrate, wherein the lower transistor is between the first cell boundary and the second cell boundary in the horizontal direction; front-side routing tracks on the upper transistor, wherein the front-side routing tracks are between the first cell boundary and the second cell boundary in the horizontal direction; back-side routing tracks on a lower surface of the substrate that is opposite to the upper surface of the substrate in the vertical direction, wherein the back-side routing tracks are between the first cell boundary and the second cell boundary in the horizontal direction; a front-side power delivery network that is adjacent one of the front-side routing tracks; and a back-side power delivery network that is adjacent one of the back-side routing tracks, wherein the front-side power delivery network overlaps the first cell boundary in the vertical direction, and wherein the back-side power delivery network overlaps the second cell boundary in the vertical direction.

An integrated circuit device, according to some embodiments, may include a first cell structure; a second cell structure that is bounded by the first cell structure with a first cell boundary therebetween in a horizontal direction; a third cell structure that is bounded by the first cell structure with a second cell boundary therebetween in the horizontal direction; a front-side power delivery network that overlaps the first cell structure and the second cell structure in a vertical direction at the first cell boundary; and a back-side power delivery network that overlaps the first cell structure and the third cell structure in the vertical direction at the second cell boundary, wherein the first cell boundary and the second cell boundary are on opposite sides of the first cell structure in the horizontal direction, wherein each of the first cell structure, the second cell structure, and the third cell structure includes an upper transistor on a substrate, a lower transistor between the upper transistor and the substrate in the vertical direction, front-side routing tracks on the upper transistor, and back-side routing tracks on a lower surface of the substrate, wherein the upper transistor has a first side surface and a second side surface that are opposite to each other in the horizontal direction, wherein the lower transistor has a third side surface and a fourth side surface that are opposite to each other in the horizontal direction, wherein the first side surface of the upper transistor, the second side surface of the upper transistor, the third side surface of the lower transistor, and the fourth side surface of the lower transistor are free of overlap with each other in the vertical direction, wherein the front-side power delivery network is on the upper transistor of the first cell structure and the upper transistor of the second cell structure, wherein the front-side power delivery network is between the front-side routing tracks of the first cell structure and the front-side routing tracks of the second cell structure in the horizontal direction, wherein the back-side power delivery network is on the lower surface of the substrate in the first cell structure and the third cell structure, wherein the back-side power delivery network is between the back-side routing tracks of the first cell structure and the back-side routing tracks of the third cell structure in the horizontal direction, wherein the vertical direction is perpendicular to an upper surface of the substrate, wherein the horizontal direction is parallel with the upper surface of the substrate, and wherein the lower surface of the substrate is opposite to the upper surface of the substrate in the vertical direction.

An integrated circuit device, according to some embodiments, may include a first cell structure; a second cell structure that is bounded by the first cell structure with a first cell boundary therebetween in a horizontal direction; a third cell structure that is bounded by the first cell structure with a second cell boundary therebetween in the horizontal direction; a front-side power delivery network that overlaps the first cell structure and the second cell structure in a vertical direction at the first cell boundary; and a back-side power delivery network that overlaps the first cell structure and the third cell structure in the vertical direction at the second cell boundary, wherein the first cell boundary and the second cell boundary are on opposite sides of the first cell structure in the horizontal direction, wherein each of the first cell structure, the second cell structure, and the third cell structure includes an upper transistor on a substrate, a lower transistor between the upper transistor and the substrate in the vertical direction, front-side routing tracks on the upper transistor, an upper contact between the upper transistor and the front-side routing tracks in the vertical direction, back-side routing tracks on a lower surface of the substrate, and a lower contact between the lower transistor and the back-side routing tracks in the vertical direction, wherein the upper transistor has a first side surface and a second side surface that are opposite to each other in the horizontal direction, wherein the lower transistor has a third side surface and a fourth side surface that are opposite to each other in the horizontal direction, wherein the first side surface of the upper transistor, the second side surface of the upper transistor, the third side surface of the lower transistor, and the fourth side surface of the lower transistor are free of overlap with each other in the vertical direction, wherein the front-side power delivery network is on the upper transistor of the first cell structure and the upper transistor of the second cell structure, wherein the front-side power delivery network is between the front-side routing tracks of the first cell structure and the front-side routing tracks of the second cell structure in the horizontal direction, wherein the back-side power delivery network is on the lower surface of the substrate in the first cell structure and the third cell structure, wherein the back-side power delivery network is between the back-side routing tracks of the first cell structure and the back-side routing tracks of the third cell structure in the horizontal direction, wherein the upper contact of the first cell structure and the upper contact of the second cell structure are connected to each other, wherein the lower contact of the first cell structure and the lower contact of the third cell structure are connected to each other, wherein the vertical direction is perpendicular to an upper surface of the substrate, wherein the horizontal direction is parallel with the upper surface of the substrate, and wherein the lower surface of the substrate is opposite to the upper surface of the substrate in the vertical direction.

### BRIEF DESCRIPTION OF THE DRAWINGS

FIGS. 1A, 1B, and 1C are plan views and a cross-sectional view of an integrated circuit device according to some embodiments.

FIG. 2 is a cross-sectional view of an integrated circuit device according to some embodiments.

### DETAILED DESCRIPTION OF EMBODIMENTS

Pursuant to embodiments herein, an integrated circuit device may comprise a cell structure comprising a substrate, a first cell boundary, and a second cell boundary that is opposite to the first cell boundary with respect to the cell structure. The integrated circuit device may further comprise a first transistor (e.g., a lower transistor) and a second transistor (e.g., an upper transistor) vertically stacked on the substrate. The first transistor may comprise first channel layers (e.g., lower channel layers) that are spaced apart from each other in a vertical direction that is perpendicular to an upper surface of the substrate. The first transistor may further comprise a first work function layer (e.g., a lower work function layer) on the first channel layers. The first transistor may further comprise first gate insulators (e.g., lower gate insulators) between the first work function layer and the first channel layers, and a first gate electrode (e.g., a lower gate electrode) on the first work function layer. The second transistor may comprise second channel layers (e.g., upper channel layers) that are spaced apart from each other in the vertical direction. The second transistor may further comprise a second work function layer (e.g., an upper work function layer) on the second channel layers. The second transistor may further comprise second gate insulators (e.g., upper gate insulators) between the second work function layer and the second channel layers, and a second gate electrode (e.g., an upper gate electrode) on the second work function layer. In some embodiments, each of the first channel layers and each of the second channel layers may be a nanosheet or a nanowire. The integrated circuit device may further comprise an insulator (also referred to as an inter-gate insulator or a middle dielectric isolation) between the first transistor (e.g., the first channel layers) and the second transistor (e.g., the second channel layers) in the vertical direction. The first transistor, the second transistor, and the insulator may be between the first cell boundary and the second cell boundary in the horizontal direction. The first transistor and the second transistor may be staggered (or offset in the horizontal direction) to form a z-shape 3D stacked transistors. The integrated circuit device may further include front-side routing tracks on the second transistor, and back-side routing tracks on a lower surface of the substrate. The front-side routing tracks and the back-side routing tracks may be between the first cell boundary and the second cell boundary in the horizontal direction. The front-side routing tracks and the back-side routing tracks may not overlap the first cell boundary and the second cell boundary in the vertical direction. The front-side routing tracks and/or the back-side routing tracks may be configured to perform as signal tracks. The integrated circuit device may further include a front-side power delivery network that is adjacent one of the front-side routing tracks, and a back-side power delivery network that is adjacent one of the back-side routing tracks. The front-side power delivery network may overlap the first cell boundary in the vertical direction, and the back-side power delivery network may overlap the second cell boundary in the vertical direction. The front-side power delivery network and the back-side power deliver network may be shared by adjacent cell structures.

Example embodiments will be described in greater detail with reference to the attached figures.

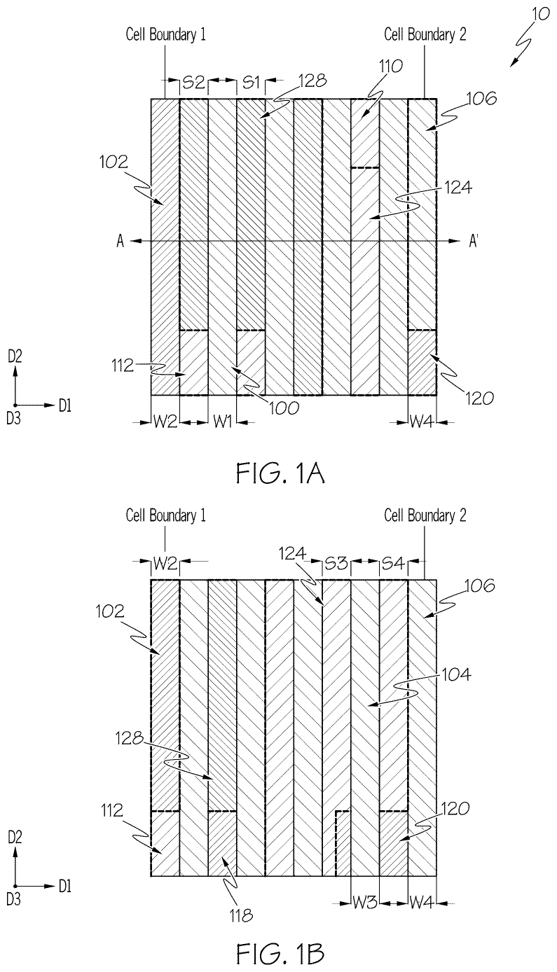

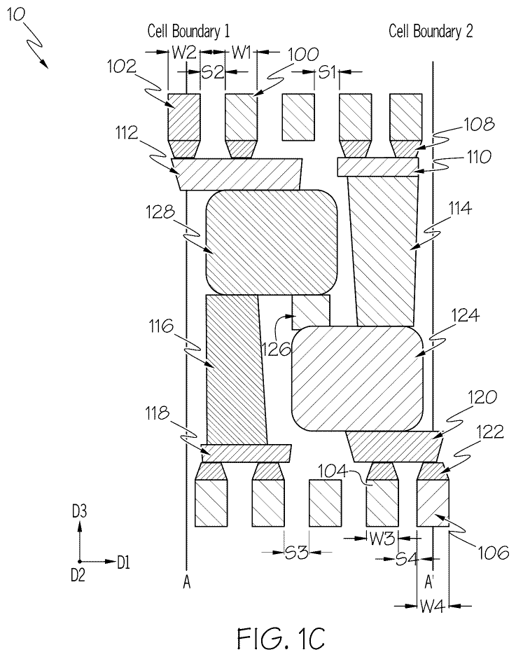

FIGS. 1A, 1B, and 1C are plan views and a cross-sectional view of an integrated circuit device 10 according to some embodiments. FIG. 1A may be a plan view from an upper side of the integrated circuit device 10. For example, FIG. 1A may be a bird's eye view of the top of the integrated circuit device 10. FIG. 1B may be a plan view from a lower side or the bottom of the integrated circuit device 10. FIG. 1C may be a cross-sectional view taken along A-A′ of FIG. 1A.

Referring to FIGS. 1A, 1B, and 1C, the integrated circuit device 10 may include a cell structure that has a first cell boundary (e.g., cell boundary 1) and a second cell boundary (e.g., cell boundary 2) that is spaced apart from the first cell boundary in a horizontal direction that is parallel with an upper surface of a substrate (not illustrated). For example, the first cell boundary and the second cell boundary may be spaced apart from each other in a first horizontal direction D1 that is parallel with the upper surface of the substrate. The cell structure may be between the first cell boundary and the second cell boundary in the first horizontal direction D1. The second cell boundary may be opposite to the first cell boundary with respect to the cell structure in the first horizontal direction D1. For example, the cell structure may refer to a region that includes various elements of the integrated circuit device 10 between the first cell boundary and the second cell boundary in the first horizontal direction D1.

The substrate (not illustrated) may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate may be a bulk substrate (e.g., a silicon wafer), a semiconductor on insulator (SOI) substrate or an insulating layer (e.g., a monolithic insulating layer). The low-k material may have a lower dielectric constat than that of silicon oxide (e.g., SiO). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric.

Referring to FIGS. 1A, 1B, and 1C, the integrated circuit device 10 may include a first transistor 124 (e.g., a lower transistor 124) and a second transistor 128 (e.g., an upper transistor 128) formed on the substrate. The first transistor 124 may be between (the upper surface of) the substrate and the second transistor 128 in a vertical direction that is perpendicular to the upper surface and/or a lower surface of the substrate. Herein, the vertical direction may refer to a third direction D3 in the drawings. In some embodiments, the first transistor 124 and the second transistor 128 may be staggered in the first horizontal direction D1. For example, the center (or a central portion) of the first transistor 124 and the center (or a central portion) of the second transistor 128 may not overlap (e.g., may be misaligned with) each other in the third direction D3. For example, the center (or the central portion) of the first transistor 124 and the center (or the central portion) of the second transistor 128 may be offset from each other in the first horizontal direction D1. In some embodiments, the first transistor 124 may have a first side surface and a second side surface that is opposite to the first side surface in the first horizontal direction D1, and the second transistor 128 may have a third side surface and a fourth side surface that is opposite to the third side surface in the first horizontal direction D1. The first side surface and the second side surface of the first transistor 124 and the third side surface and the fourth side surface of the second transistor 128 may not overlap with each other in the third direction D3. For example, a plane of the first side surface of the first transistor 124 may be between respective planes of the third side surface and the fourth side surface of the second transistor 128 in the first horizontal direction D1. However, the relative locations of the first transistor 124 and the second transistor 128 are not limited to the embodiments described above. The staggered structure of the first transistor 124 and the second transistor 128 may be referred to as a z-shape 3D stacked device (e.g., z-shape 3D stacked field effect transistor (z-shape 3DSFET)).

The first transistor 124 and the second transistor 128 may have different conductivity types or the same conductivity type. In some embodiments, the first transistor 124 may be an N-type transistor including an N-type source/drain region (not illustrated), and the second transistor 128 may be a P-type transistor including a P-type source/drain region (not illustrated). However, the inventive concepts of the types of the first transistor 124 and the second transistor 128 are not limited to the embodiments described above. For example, the first transistor 124 may be a P-type transistor including a P-type source/drain region (not illustrated), and the second transistor 128 may be an N-type transistor including an N-type source/drain region (not illustrated). The first transistor 124 and the second transistor 128 may be implemented using various types of transistors (e.g., a planar transistor, a gate-all-around field-effect transistor (GAA FET), a recessed channel array transistor (RCAT), a fin field-effect transistor (FinFET), or multi-bridge-channel field effect transistor (MBCFET™)). Hereinafter, the first transistor 124 and the second transistor 128 are described as MBCFETs™ for the convenience of the description, but the types of the first transistor 124 and the second transistor 128 are not limited thereto.

Although not illustrated in FIGS. 1A, 1B, and 1C, the first transistor 124 may comprise first channel layers (e.g., lower channel layers) and a first work function layer (e.g., a lower work function layer) on the first channel layers. The first transistor 124 may further comprise first gate insulators (e.g., lower gate insulators) on the first channel layers, and a first gate electrode (e.g., a lower gate electrode) on the first work function layer. For example, the first gate insulators may be between the first channel layers and the first work function layer. The first gate insulators, the first work function layer, and the first gate electrode may be collectively referred to as a first gate structure (e.g., a lower gate structure).

The first channel layers may be spaced apart from each other in the vertical direction. In some embodiments, the first channel layers may be spaced apart from each other at equal or substantially equal distance in the vertical direction. In some embodiments, each of the first channel layers may have an equal or a substantially equal width in the first horizontal direction D1 and a second horizontal direction D2 that is parallel with an upper surface of the substrate and intersects the first horizontal direction D1. The second horizontal direction D2 may be perpendicular to the first horizontal direction D1. Herein, “substantially” may mean no greater than a 10% deviation. For example, when element X has a width of 10 nm and a width of element Y is substantially equal to that of element X, the width of element Y may not be less than 9 nm or greater than 11 nm.

The first gate insulators may extend around (e.g., at least partially surround) the first channel layers, respectively. The first work function layer may extend around (e.g., at least partially surround) the first gate insulators (and the first channel layers). The first gate electrode may extend around (e.g., at least partially surround) the first work function layer.

In some embodiments, the first channel layers may include semiconductor material(s), for example, Si, Ge, SiGe, GaP, GaAs, SiC, SiGeC and/or InP. In some embodiments, the first gate insulators may include insulator(s), for example, silicon oxide, silicon oxynitride, silicon nitride, silicon carbonitride and/or a low-k material that has a lower dielectric constant than that of silicon oxide. In some embodiments, the first work function layer may include, for example, a TiN layer, a TaN layer, a TiAl layer, a TiC layer, a TiAlC layer, a TiAlN layer and/or a WN layer. In some embodiments, the first gate electrode may include, for example, tungsten (W), aluminum (Al) and/or copper (Cu). However, the materials of the first channel layers, the first gate insulators, the first work function layer, and the first gate electrode are not limited to the embodiments described above. In some embodiments, the first gate insulators and the first gate electrode may be omitted.

Although not illustrated in FIGS. 1A, 1B, and 1C, the second transistor 128 may comprise second channel layers (e.g., upper channel layers) and a second work function layer (e.g., an upper work function layer) on the second channel layers. The second transistor 128 may further comprise second gate insulators (e.g., upper gate insulators) on the second channel layers, and a second gate electrode (e.g., an upper gate electrode) on the second work function layer. For example, the second gate insulators may be between the second channel layers and the second work function layer. The second gate insulators, the second work function layer, and the second gate electrode may be collectively referred to as a second gate structure (e.g., an upper gate structure).

The second channel layers may be spaced apart from each other in the vertical direction. In some embodiments, the second channel layers may be spaced apart from each other at equal or substantially equal distance in the vertical direction. In some embodiments, each of the second channel layers may have an equal or a substantially equal width in the first horizontal direction D1 and/or the second horizontal direction D2. In some embodiments the width of the first channel layers in the first horizontal direction D1 may be greater than the width of the second channel layers in the horizontal direction D2, but the relative widths of the first channel layers and the second channel layers in the first horizontal direction D1 are not limited thereto.

The second gate insulators may extend around (e.g., at least partially surround) the second channel layers, respectively. The second work function layer may extend around (e.g., at least partially surround) the second gate insulators. The second gate electrode may extend around (e.g., at least partially surround) the second work function layer.

In some embodiments, the second channel layers may include semiconductor material(s), for example, Si, Ge, SiGe, GaP, GaAs, SiC, SiGeC and/or InP. In some embodiments, the second gate insulators may include insulator(s), for example, silicon oxide, silicon oxynitride, silicon nitride, silicon carbonitride and/or a low-k material that has a lower dielectric constant than that of silicon oxide. In some embodiments, the second work function layer may include, for example, a TiN layer, a TaN layer, a TiAl layer, a TiC layer, a TiAlC layer, a TiAlN layer and/or a WN layer In some embodiments, the second gate electrode may include, for example, tungsten (W), aluminum (Al) and/or copper (Cu). However, the materials of the second channel layers, the second gate insulators, the second work function layer, and the second gate electrode are not limited to the embodiments described above. In some embodiments, the second gate insulators and the second gate electrode may be omitted.

In some embodiments, each of the first channel layers and the second channel layers may be a nanosheet (that may have a thickness in a range of from 1 nm to 100 nm in the vertical direction) or may be a nanowire (that may have a circular cross-section with a diameter in a range of from 1 nm to 100 nm). The number of the first channel layers and the number of the second channel layers may vary.

The integrated circuit device 10 may include an insulator 126 (also referred to as an inter-gate insulator 126 or a middle dielectric isolation 126) between the first transistor 124 and the second transistor 128 in the third direction D3. The insulator 126 may include insulator(s), for example, silicon nitride (e.g., SiN). However, the material of the insulator 126 is not limited thereto.

The integrated circuit device 10 may include front-side routing tracks 100 on (the upper surface of) the second transistor 128. The front-side routing tracks 100 may be spaced apart from each other in the first horizontal direction D1. Although not illustrated, an interlayer insulating layer may extend around (e.g., at least partially surround) the front-side routing tracks 100. The front-side routing tracks 100 may be spaced apart from each other by a first distance S1 in the first horizontal direction D1. In some embodiments, each of the front-side routing tracks 100 may have the same or substantially the same width in the first horizontal direction D1. For example, each of the front-side routing tracks 100 may have a first width W1 in the first horizontal direction D1. In some embodiments, the first distance S1 between adjacent ones of the front-side routing tracks 100 may be equal or substantially equal to the first width W1 of the front-side routing tracks 100.

The front-side routing tracks 100 may be within the cell structure. For example, the front-side routing tracks 100 may be between the first cell boundary and the second cell boundary in the first horizontal direction D1. The front-side routing tracks 100 may not overlap the first cell boundary and the second cell boundary in the third direction D3. Although four (4) front-side routing tracks 100 are illustrated in FIGS. 1A, 1B, and 1C, the number of the front-side routing tracks 100 is not limited thereto. In some embodiments, the front-side routing tracks 100 may include a conductive material, such as a metal. For example, the front-side routing tracks 100 may include copper, aluminum, and/or tungsten, but not limited thereto. In some embodiments, the front-side routing tracks 100 may be configured to perform as signal transfer paths (tracks) for the integrated circuit device 10.

The integrated circuit device 10 may include a front-side power delivery network (FSPDN) 102 on (the upper surface of) the second transistor 128. The front-side power delivery network 102 may be adjacent one of the front-side routing tracks 100. The front-side power delivery network 102 may be spaced apart from the one of the front-side routing tracks 100 by a second distance S2 in the first horizontal direction D1. In some embodiments, the second distance S2 may be equal or substantially equal to the first distance S1. The front-side power delivery network 102 may have a second width W2 in the first horizontal direction D1. The second width W2 of the front-side power delivery network 102 may be greater than the first width W1 of the front-side routing tracks 100. The front-side power delivery network 102 may be at the first cell boundary. In some embodiments, the front-side power delivery network 102 may overlap the first cell boundary in the third direction D3. For example, the front-side power delivery network 102 may be shared by cell structures adjacent each other in the first horizontal direction D1.

In some embodiments, the front-side power delivery network 102 may include a conductive material, such as a metal. For example, the front-side power delivery network 102 may include copper, aluminum, and/or tungsten, but not limited thereto. In some embodiments, the front-side power delivery network 102 may be configured to perform as a power delivery path for the integrated circuit device 10. The front-side power delivery network 102 may be adjacent the second transistor 128. For example, the front-side power delivery network 102 may be closer to the second transistor 128 than the first transistor 124. The front-side power delivery network 102 may be electrically connected to the second transistor 128.

The back-side routing tracks 104 may be on (below)/in the substrate. The back-side routing tracks 104 may be on a lower surface of the substrate. For example, the integrated circuit device 10 may include back-side routing tracks 104 on (below) the first transistor 124. Although not illustrated, an interlayer insulating layer may extend around (e.g., at least partially surround) the back-side routing tracks 104. The back-side routing tracks 104 may be spaced apart from each other in the first horizontal direction D1. The back-side routing tracks 104 may be spaced apart from each other by a third distance S3 in the first horizontal direction D1. In some embodiments, each of the back-side routing tracks 104 may have the same or substantially the same width in the first horizontal direction D1. For example, each of the back-side routing tracks 104 may have a third width W3 in the first horizontal direction D1. In some embodiments, the third distance S3 between adjacent ones of the back-side routing tracks 104 may be equal or substantially equal to the third width W3 of the back-side routing tracks 104.

The back-side routing tracks 104 may be within the cell structure. For example, the back-side routing tracks 104 may be between the first cell boundary and the second cell boundary in the first horizontal direction D1. The back-side routing tracks 104 may not overlap the first cell boundary and the second cell boundary in the third direction D3. Although four (4) back-side routing tracks 104 are illustrated in FIGS. 1A, 1B, and 1C, the number of the back-side routing tracks 104 is not limited thereto. In some embodiments, the number of the back-side routing tracks 104 may be the same as the number of the front-side routing tracks 100. In some embodiments, the back-side routing tracks 104 may include a conductive material, such as a metal. For example, the back-side routing tracks 104 may include copper, aluminum, and/or tungsten, but not limited thereto. In some embodiments, the back-side routing tracks 104 may be configured to perform as signal transfer paths (tracks) for the integrated circuit device 10.

The integrated circuit device 10 may include a back-side power delivery network (BSPDN) 106 on (below)/in the substrate. The back-side power delivery network 106 may be on the lower surface of the substrate. In some embodiments, the back-side power delivery network 106 may be on (below) the first transistor 124. The back-side power delivery network 106 may be adjacent one of the back-side routing tracks 104. The back-side power delivery network 106 may be spaced apart from the one of the back-side routing tracks 104 by a fourth distance S4 in the first horizontal direction D1. In some embodiments, the fourth distance S4 may be equal or substantially equal to the third distance S3. The back-side power delivery network 106 may have a fourth width W4 in the first horizontal direction D1. The fourth width W4 of the back-side power delivery network 106 may be greater than the third width W3 of the back-side routing tracks 104. The back-side power delivery network 106 may be at the second cell boundary. In some embodiments, the back-side power delivery network 106 may overlap the second cell boundary in the third direction D3. For example, the back-side power delivery network 106 may be shared by cell structures adjacent each other in the first horizontal direction D1. In some embodiments, the front-side power delivery network 102 and the back-side power delivery network 106 may be opposite to each other (with respect to the cell structure) in the first horizontal direction D1 and the third direction D3. For example, the front-side power delivery network 102 and the back-side power delivery network 106 may be opposite sides of the cell structure in the first horizontal direction D1 and the third direction D3.

In some embodiments, the back-side power delivery network 106 may include a conductive material, such as a metal. For example, the back-side power delivery network 106 may include copper, aluminum, and/or tungsten, but not limited thereto. In some embodiments, the back-side power delivery network 106 may be configured to perform as a power delivery path for the integrated circuit device 10. The back-side power delivery network 106 may be adjacent the first transistor 124. For example, the back-side power delivery network 106 may be closer to the first transistor 124 than the second transistor 128. The back-side power delivery network 106 may be electrically connected to the first transistor 124.

In some embodiments, the first width W1 of the front-side routing tracks 100 may be equal or substantially equal to the third width W3 of the back-side routing tracks 104. In some embodiments, the first distance S1 between the adjacent ones of the front-side routing tracks 100 may be equal or substantially equal to the third distance S3 between the adjacent ones of the back-side routing tracks 104. In some embodiments, the front-side routing tracks 100 and the back-side routing tracks 104 may be staggered (offset from each other) in the first horizontal direction D1 by a half pitch. For example, the front-side routing tracks 100 do not overlap the back-side routing tracks 104 in the third direction D3.

The integrated circuit device 10 may further include a middle-of-line (MOL) structure. The MOL structure may include interlayer insulating layer(s) in which conductive wire(s) (e.g., metal wire(s)) and conductive via plug(s) (e.g., metal via plug(s)) are provided. Various elements of the first transistor 124 and the second transistor 128 may be (electrically) connected to one of the conductive wires of the MOL. In some embodiments, the front-side routing tracks 100, the front-side power delivery network 102, the back-side routing tracks 104, and/or the back-side power delivery network 106 may be electrically connected to the first transistor 124 and/or the second transistor 128 through the MOL structure. However, the MOL structure is not limited to the embodiments described above. For example, the MOL structure may include an additional element that is not described above, or some of the elements of the MOL structure described above may be omitted.

Referring to FIGS. 1A, 1B, and 1C, for example, the MOL structure may include front-side vias 108, a front-side middle layer 110, an upper-epi contact 112, a front-side contact 114, a back-side contact 116, a back-side middle layer 118, and a lower-epi contact 120, and back-side vias 122. The upper-epi contact 112 may be between the second transistor 128 and the front-side power delivery network 102 in the third direction D3. The upper-epi contact 112 may be between the second transistor 128 and the front-side routing tracks 100 in the third direction D3. The front-side via 108 may be between the upper-epi contact 112 and the front-side power delivery network 102 in the third direction D3. The front-side via 108 may be between the upper-epi contact 112 and the front-side routing track 100. For example, the front-side routing tracks 100 and the front-side power delivery network 102 may be electrically connected to the second transistor 128 through the front-side vias 108 and the upper-epi contact 112. However, the MOL structure is not limited to the embodiments described above.

Referring to FIGS. 1A, 1B, and 1C, for example, the lower-epi contact 120 may be between the first transistor 124 and the back-side power delivery network 106 in the third direction D3. The lower-epi contact 120 may be between the first transistor 124 and the back-side routing tracks 104 in the third direction D3. The back-side via 122 may be between the lower-epi contact 120 and the back-side power delivery network 106 in the third direction D3. The back-side via 122 may be between the lower-epi contact 120 and the back-side routing track 104. For example, the back-side routing tracks 104 and the back-side power delivery network 106 may be electrically connected to the first transistor 124 through the back-side vias 122 and the lower-epi contact 120. However, the MOL structure is not limited to the embodiments described above.

Referring to FIGS. 1A, 1B, and 1C, for example, the back-side middle layer 118 may be between the back-side vias 122 and the second transistor 128 in the third direction D3. The back-side contact 116 may be between the back-side middle layer 118 and the second transistor 128 in the third direction D3. The back-side routing tracks 104 may be electrically connected to the second transistor 128 through the back-side vias 122, the back-side middle layer 118, and the back-side contact 116. However, the MOL structure is not limited to the embodiments described above.

Referring to FIGS. 1A, 1B, and 1C, for example, the front-side middle layer 110 may be between the front-side vias 108 and the first transistor 124 in the third direction D3. The front-side contact 114 may be between the front-side middle layer 110 and the first transistor 124 in the third direction D3. The front-side routing tracks 100 may be electrically connected to the first transistor 124 through the front-side vias 108, the front-side middle layer 110, and the front-side contact 114. However, the MOL structure is not limited to the embodiments described above.

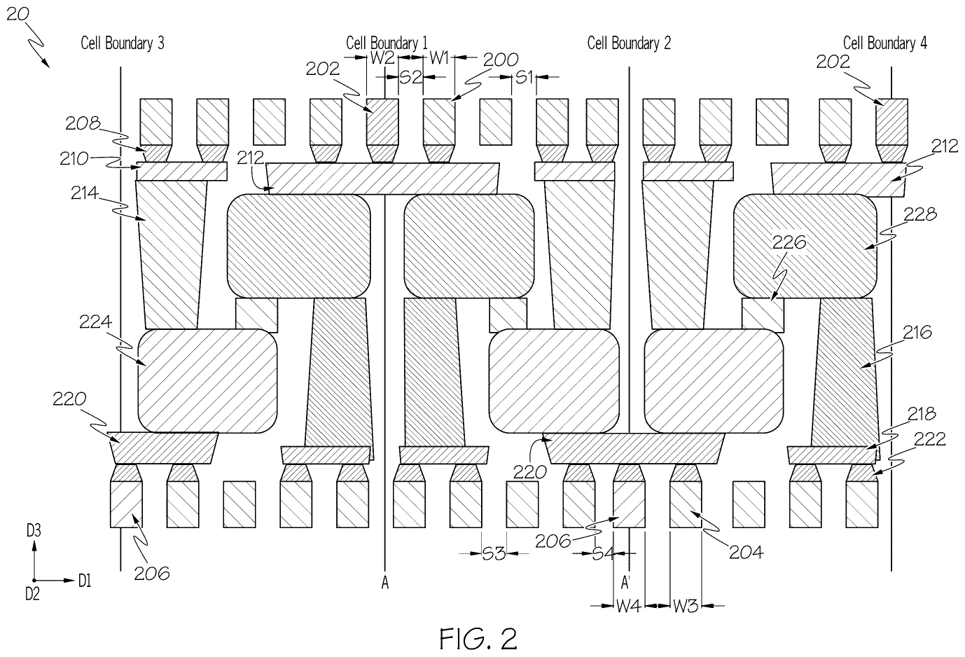

FIG. 2 is a cross-sectional view of an integrated circuit device 20 according to some embodiments. Since the integrated circuit device 20 may be (at least partially) formed and configured similarly as the integrated circuit device 10 in FIGS. 1A, 1B, and 1C, detailed descriptions of the common configuration with the integrated circuit device 10 may be omitted, and differences from the integrated circuit device 10 will be described in detail. The front-side routing tracks 200, the front-side power delivery network 202, the back-side routing tracks 204, the back-side power delivery network 206, the front-side vias 208, the front-side middle layer 210, the upper-epi contact 212, the front-side contact 214, the back-side contact 216, the back-side middle layer 218, the lower-epi contact 220, the back-side vias 222, the first transistor 224, the insulator 226, and the second transistor 228 may correspond to the front-side routing tracks 100, the front-side power delivery network 102, the back-side routing tracks 104, the back-side power delivery network 106, the front-side vias 108, the front-side middle layer 110, the upper-epi contact 112, the front-side contact 114, the back-side contact 116, the back-side middle layer 118, the lower-epi contact 120, the back-side vias 122, the first transistor 124, the insulator 126, and the second transistor 128, respectively.

Referring to FIG. 2, the integrated circuit device 20 may include a first cell structure, a second cell structure, and a third cell structure. Each of the first cell structure, the second cell structure, and the third cell structure may include the front-side routing tracks 200, the back-side routing tracks 204, the front-side vias 208, the front-side middle layer 210, the upper-epi contact 212, the front-side contact 214, the back-side contact 216, the back-side middle layer 218, the lower-epi contact 220, the back-side vias 222, the first transistor 224, the insulator 226, and the second transistor 228. However, the embodiments of the first cell structure, the second cell structure, and the third cell structure are not limited to the embodiments described above. Since the second cell structure and the third cell structure may be formed and configured similarly as the first cell structure, detailed descriptions of the common configuration may be omitted.

In some embodiments, the second cell structure may be bounded by the first cell structure with the first cell boundary (e.g., cell boundary 1) therebetween in the first horizontal direction D1. The third cell structure may be bounded by the first cell structure with the second cell boundary (e.g., cell boundary 2) therebetween in the first horizontal direction D1. For example, the second cell structure and the third cell structure may be on the opposite sides of the first cell structure in the first horizontal direction D1. The second cell structure may include a third cell boundary (e.g., cell boundary 3) opposite to the first cell boundary in the first horizontal direction D1. The third cell structure may include a fourth cell boundary (e.g., cell boundary 4) opposite to the second cell boundary in the first horizontal direction D1.

One of the front-side power delivery networks 202 may overlap the first cell structure and the second cell structure in the third direction D3 at the first cell boundary. For example, the one of the front-side power delivery networks 202 may overlap the first cell boundary in the third direction D3. Another one of the front-side power delivery networks 202 may overlap the fourth cell boundary in the third direction D3. The one of the front-side power delivery networks 202 may be shared by the first cell structure and the second cell structure. The one of the front-side power delivery networks 202 may be on the second transistor 228 of the first cell structure and the second transistor 228 of the second cell structure. The one of the front-side power delivery networks 202 may be between the front-side routing tracks 200 of the first cell structure and the front-side routing tracks 200 of the second cell structure in the first horizontal direction D1. In some embodiments, the one of the front-side power delivery networks 202 may be electrically connected to the second transistor 228 of the first cell structure and the second transistor 228 of the second cell structure. In some embodiments, the one of the front-side power delivery networks 202 may be electrically connected to the second transistor 228 of the first cell structure and the second transistor 228 of the second cell structure through the upper-epi contact 212 of the first cell structure and the upper-epi contact 212 of the second cell structure. In some embodiments, the upper-epi contact 212 of the first cell structure and the upper-epi contact 212 of the second cell structure may be connected to each other. For example, the upper-epi contact 212 of the first cell structure and the upper-epi contact 212 of the second cell structure may be connected to each other to form an integrated structure (e.g., a single monolithic structure).

One of the back-side power delivery networks 206 may overlap the first cell structure and the third cell structure in the third direction D3 at the second cell boundary. For example, the one of the back-side power delivery networks 206 may overlap the second cell boundary in the third direction D3. Another one of the back-side power delivery networks 206 may overlap the third cell boundary in the third direction D3. The one of the back-side power delivery networks 206 may be shared by the first cell structure and the third cell structure. The one of the back-side power delivery networks 206 may be on (a lower surface of) the substrate (e.g., on the first transistor 224) of the first cell structure and on (a lower surface of) the substrate (e.g., on the first transistor 224) of the third cell structure. The one of the back-side power delivery networks 206 may be between the back-side routing tracks 204 of the first cell structure and the back-side routing tracks 204 of the third cell structure in the first horizontal direction D1. In some embodiments, the one of the back-side power delivery networks 206 may be electrically connected to the first transistor 224 of the first cell structure and the first transistor 224 of the third cell structure. In some embodiments, the one of the back-side power delivery networks 206 may be electrically connected to the first transistor 224 of the first cell structure and the first transistor 224 of the third cell structure through the lower-epi contact 220 of the first cell structure and the lower-epi contact 220 of the third cell structure. In some embodiments, the lower-epi contact 220 of the first cell structure and the lower-epi contact 220 of the third cell structure may be connected to each other. For example, the lower-epi contact 220 of the first cell structure and the lower-epi contact 220 of the third cell structure may be connected to each other to form an integrated structure (e.g., a single monolithic structure).

In some embodiments, the first cell structure and the second cell structure may be symmetrical (e.g., mirror-imaged) to each other with respect to the first cell boundary. For example, the first cell structure and the second cell structure may be symmetrical (e.g., mirror-imaged) to each other with respect to the one of the front-side power delivery networks 202 in the first horizontal direction D1. In some embodiments, the first cell structure and the third cell structure may be symmetrical (e.g., mirror-imaged) to each other with respect to the second cell boundary. For example, the first cell structure and the third cell structure may be symmetrical (e.g., mirror-imaged) to each other with respect to the one of the back-side power delivery networks 206 in the first horizontal direction D1.

Example embodiments described herein may scale down the cell height of the integrated circuit device while improving (e.g., optimizing) the process margin (for the MOL and back end-of-line (BEOL)) by utilizing the staggered transistors, the shared FSPDN, and/or the shared BSPDN. The reliability of the integrated circuit device may be improved by the improved process margin. The performance of the integrated circuit device may be improved as the source resistance is reduced and/or the power supply paths are increased and diversified (into both the front-side and the back-side of the integrated circuit device).

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present inventive concepts to those skilled in the art. In the drawings, the sizes and relative sizes of layers and regions may be exaggerated for clarity. Like reference numbers may refer to like elements throughout unless clearly stated otherwise.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

As used herein, “an element A overlapping an element B in a direction X” (or similar language) means that there is at least one line that extends in the direction X and intersects both the elements A and B.

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments. Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination.

The above-disclosed subject matter is to be considered illustrative, and not restrictive, and the appended claims are intended to cover all such modifications, enhancements, and other embodiments, which fall within the scope of the present inventive concepts. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a cell structure that comprises:
a substrate;
a first cell boundary; and
a second cell boundary that is opposite to the first cell boundary with respect to the cell structure in a horizontal direction that is parallel with an upper surface of the substrate;
an upper transistor on the upper surface of the substrate, wherein the upper transistor is between the first cell boundary and the second cell boundary in the horizontal direction;
a lower transistor between the upper surface of the substrate and the upper transistor in a vertical direction that is perpendicular to the upper surface of the substrate, wherein the lower transistor is between the first cell boundary and the second cell boundary in the horizontal direction;
front-side routing tracks on the upper transistor, wherein the front-side routing tracks are between the first cell boundary and the second cell boundary in the horizontal direction;
back-side routing tracks on a lower surface of the substrate that is opposite to the upper surface of the substrate in the vertical direction, wherein the back-side routing tracks are between the first cell boundary and the second cell boundary in the horizontal direction;
a front-side power delivery network that is adjacent one of the front-side routing tracks; and
a back-side power delivery network that is adjacent one of the back-side routing tracks,
wherein the front-side power delivery network overlaps the first cell boundary in the vertical direction, and
wherein the back-side power delivery network overlaps the second cell boundary in the vertical direction.

2. The integrated circuit device of claim 1, wherein the front-side power delivery network is electrically connected to the upper transistor, and
wherein the back-side power delivery network is electrically connected to the lower transistor.

3. The integrated circuit device of claim 2, wherein the upper transistor has a first side surface and a second side surface that are opposite to each other in the horizontal direction,
wherein the lower transistor has a third side surface and a fourth side surface that are opposite to each other in the horizontal direction, and
wherein the first side surface of the upper transistor, the second side surface of the upper transistor, the third side surface of the lower transistor, and the fourth side surface of the lower transistor are free of overlap with each other in the vertical direction.

4. The integrated circuit device of claim 3, wherein the third side surface of the lower transistor is between the first side surface of the upper transistor and the second side surface of the upper transistor in the horizontal direction.

5. The integrated circuit device of claim 3, wherein the front-side routing tracks are spaced apart from each other in the horizontal direction at a first distance, and
wherein the back-side routing tracks are spaced apart from each other in the horizontal direction at a second distance.

6. The integrated circuit device of claim 5, wherein the front-side power delivery network is spaced apart from the adjacent one of the front-side routing tracks in the horizontal direction at the first distance, and
wherein the back-side power delivery network is spaced apart from the adjacent one of the back-side routing tracks in the horizontal direction at the second distance.

7. The integrated circuit device of claim 6, wherein each of the front-side routing tracks has a first width in the horizontal direction, and
wherein the front-side power delivery network has a second width in the horizontal direction that is greater than the first width.

8. The integrated circuit device of claim 7, wherein each of the back-side routing tracks has a third width in the horizontal direction, and
wherein the back-side power delivery network has a fourth width in the horizontal direction that is greater than the third width.

9. The integrated circuit device of claim 8, wherein the first distance is equal to the first width, and
wherein the second distance is equal to the third width.

10. The integrated circuit device of claim 9, wherein the first distance is equal to the second distance.

11. The integrated circuit device of claim 10, wherein the front-side routing tracks are free of overlap with the back-side routing tracks in the vertical direction.

12. An integrated circuit device comprising:
a first cell structure;
a second cell structure that is bounded by the first cell structure with a first cell boundary therebetween in a horizontal direction;
a third cell structure that is bounded by the first cell structure with a second cell boundary therebetween in the horizontal direction;
a front-side power delivery network that overlaps the first cell structure and the second cell structure in a vertical direction at the first cell boundary; and
a back-side power delivery network that overlaps the first cell structure and the third cell structure in the vertical direction at the second cell boundary,
wherein the first cell boundary and the second cell boundary are on opposite sides of the first cell structure in the horizontal direction,
wherein each of the first cell structure, the second cell structure, and the third cell structure includes an upper transistor on a substrate, a lower transistor between the upper transistor and the substrate in the vertical direction, front-side routing tracks on the upper transistor, and back-side routing tracks on a lower surface of the substrate,
wherein the upper transistor has a first side surface and a second side surface that are opposite to each other in the horizontal direction,
wherein the lower transistor has a third side surface and a fourth side surface that are opposite to each other in the horizontal direction,
wherein the first side surface of the upper transistor, the second side surface of the upper transistor, the third side surface of the lower transistor, and the fourth side surface of the lower transistor are free of overlap with each other in the vertical direction,
wherein the front-side power delivery network is on the upper transistor of the first cell structure and the upper transistor of the second cell structure,
wherein the front-side power delivery network is between the front-side routing tracks of the first cell structure and the front-side routing tracks of the second cell structure in the horizontal direction,
wherein the back-side power delivery network is on the lower surface of the substrate in the first cell structure and the third cell structure,
wherein the back-side power delivery network is between the back-side routing tracks of the first cell structure and the back-side routing tracks of the third cell structure in the horizontal direction,
wherein the vertical direction is perpendicular to an upper surface of the substrate,
wherein the horizontal direction is parallel with the upper surface of the substrate, and
wherein the lower surface of the substrate is opposite to the upper surface of the substrate in the vertical direction.

13. The integrated circuit device of claim 12, wherein the first cell structure and the second cell structure are symmetrical to each other with respect to the front-side power delivery network in the horizontal direction, and
wherein the first cell structure and the third cell structure are symmetrical to each other with respect to the back-side power delivery network in the horizontal direction.

14. The integrated circuit device of claim 13, wherein the front-side power delivery network is electrically connected to the upper transistor of the first cell structure and the upper transistor of the second cell structure, and
wherein the back-side power delivery network is electrically connected to the lower transistor of the first cell structure and the lower transistor of the third cell structure.

15. The integrated circuit device of claim 14, wherein each of the front-side routing tracks has a first width in the horizontal direction,
wherein the front-side power delivery network has a second width in the horizontal direction that is greater than the first width,
wherein each of the back-side routing tracks has a third width in the horizontal direction, and
wherein the back-side power delivery network has a fourth width in the horizontal direction that is greater than the third width.

16. The integrated circuit device of claim 15, wherein the front-side routing tracks are free of overlap with the first cell boundary and the second cell boundary in the vertical direction, and
wherein the back-side routing tracks are free of overlap with the first cell boundary and the second cell boundary in the vertical direction.

17. An integrated circuit device comprising:
a first cell structure;
a second cell structure that is bounded by the first cell structure with a first cell boundary therebetween in a horizontal direction;
a third cell structure that is bounded by the first cell structure with a second cell boundary therebetween in the horizontal direction;
a front-side power delivery network that overlaps the first cell structure and the second cell structure in a vertical direction at the first cell boundary; and
a back-side power delivery network that overlaps the first cell structure and the third cell structure in the vertical direction at the second cell boundary,
wherein the first cell boundary and the second cell boundary are on opposite sides of the first cell structure in the horizontal direction,
wherein each of the first cell structure, the second cell structure, and the third cell structure includes an upper transistor on a substrate, a lower transistor between the upper transistor and the substrate in the vertical direction, front-side routing tracks on the upper transistor, an upper contact between the upper transistor and the front-side routing tracks in the vertical direction, back-side routing tracks on a lower surface of the substrate, and a lower contact between the lower transistor and the back-side routing tracks in the vertical direction,
wherein the upper transistor has a first side surface and a second side surface that are opposite to each other in the horizontal direction,
wherein the lower transistor has a third side surface and a fourth side surface that are opposite to each other in the horizontal direction,
wherein the first side surface of the upper transistor, the second side surface of the upper transistor, the third side surface of the lower transistor, and the fourth side surface of the lower transistor are free of overlap with each other in the vertical direction,
wherein the front-side power delivery network is on the upper transistor of the first cell structure and the upper transistor of the second cell structure,
wherein the front-side power delivery network is between the front-side routing tracks of the first cell structure and the front-side routing tracks of the second cell structure in the horizontal direction,
wherein the back-side power delivery network is on the lower surface of the substrate in the first cell structure and the third cell structure,
wherein the back-side power delivery network is between the back-side routing tracks of the first cell structure and the back-side routing tracks of the third cell structure in the horizontal direction,
wherein the upper contact of the first cell structure and the upper contact of the second cell structure are connected to each other,
wherein the lower contact of the first cell structure and the lower contact of the third cell structure are connected to each other,
wherein the vertical direction is perpendicular to an upper surface of the substrate,
wherein the horizontal direction is parallel with the upper surface of the substrate, and
wherein the lower surface of the substrate is opposite to the upper surface of the substrate in the vertical direction.

18. The integrated circuit device of claim 17, wherein the first cell structure and the second cell structure are symmetrical to each other with respect to the front-side power delivery network in the horizontal direction, and
wherein the first cell structure and the third cell structure are symmetrical to each other with respect to the back-side power delivery network in the horizontal direction.

19. The integrated circuit device of claim 18, wherein the front-side power delivery network is electrically connected to the upper transistor of the first cell structure and the upper transistor of the second cell structure through the upper contact of the first cell structure and the upper contact of the second cell structure, and
wherein the back-side power delivery network is electrically connected to the lower transistor of the first cell structure and the lower transistor of the third cell structure through the lower contact of the first cell structure and the lower contact of the third cell structure.

20. The integrated circuit device of claim 19, wherein each of the front-side routing tracks has a first width in the horizontal direction,
wherein the front-side power delivery network has a second width in the horizontal direction that is greater than the first width,
wherein each of the back-side routing tracks has a third width in the horizontal direction, and
wherein the back-side power delivery network has a fourth width in the horizontal direction that is greater than the third width.
